(19) United States
(12) Patent Application Publication
(10) Pub. No.: US 2010/0055841 A1
(43) Pub. Date: Mar. 4, 2010

(54) SEMICONDUCTOR DEVICE AND METHOD OF PRODUCING THE SAME

(76) Inventor: Nobuo OZAWA, Tokyo (JP)

Correspondence Address: Kubotera & Associates, LLC, 200 Daingerfield Rd, Suite 202, Alexandria, VA, 22314, US

(21) Appl. No.: 12/539,685

(22) Filed: Aug. 12, 2009

(30) Foreign Application Priority Data
Aug. 28, 2008 (JP) 2008-218941

(51) Int. Cl. H01L 21/50

(52) U.S. Cl. 438/113; 257/E21.499

(57) ABSTRACT

A method of producing a semiconductor device includes the steps of: preparing a semiconductor wafer having an MEMS (Micro Electro Mechanical Systems) element formed on a surface thereof; forming a groove portion surrounding the MEMS element in the surface of the semiconductor wafer; preparing a sealing wafer having a recess portion formed in a surface thereof and a protruding portion surrounding the recess portion; filling an adhesive in the groove portion; arranging the semiconductor wafer so that the surface of the semiconductor wafer faces the surface of the sealing wafer; fitting the protruding portion into the groove portion so that the recess portion covers the MEMS element; hardening the adhesive to form an MEMS element mounting wafer; and cutting the MEMS element mounting wafer into pieces to obtain the semiconductor device. Further, the adhesive is formed of a silicone type resin.

### BACKGROUND OF THE INVENTION AND RELATED ART STATEMENT

The present invention relates to a semiconductor device. More specifically, the present invention relates to a semiconductor device having an MEMS (Micro Electro Mechanical Systems) element sealed in a package. The present invention also relates to a method of producing the semiconductor device.

Patent Reference has disclosed a conventional semiconductor device. In the conventional semiconductor device, an MEMS (Micro Electro Mechanical Systems) element is formed on a semiconductor chip or a semiconductor wafer. Further, a sealing cap or a sealing wafer formed of glass and the likes seals the MEMS element with an anodic bonding method.

Patent Reference: Japanese Patent Publication No. 2006-305655

According to Patent Reference, a switch element as the MEMS element is formed on a surface of the semiconductor wafer as an MEMS element forming substrate. A protruding bonding portion of the sealing wafer as a sealing cap substrate is fitted into a recess portion of the MEMS element forming substrate. Afterward, the MEMS element forming substrate is chemically bonded with the protruding bonding portion with the anodic bonding method, so that the switch element is hermetically sealed.

After the MEMS element forming substrate is chemically bonded with the protruding bonding portion, the MEMS element forming substrate and the sealing cap substrate are cutalong a dicing region, thereby forming an MEMS element device. The recess portion functions as a positioning groove for fitting the protruding bonding portion when the switch element is hermetically sealed with the sealing cap substrate.

According to Patent Reference, when the MEMS element forming substrate is bonded with the sealing cap substrate with the anodic bonding method for sealing the switch element, the MEMS element forming substrate and the sealing cap substrate are heated to 300° C. to 400° C. Then, a voltage of 500 V to 1,000 V is applied to the MEMS element forming substrate and the sealing cap substrate. Accordingly, a large static attraction force tends to generate between the MEMS element forming substrate and the sealing cap substrate. As a result, the MEMS element forming substrate is chemically bonded with the sealing cap substrate at an interface between a surface of the MEMS element forming substrate and the protruding bonding portion.

The sealing cap substrate as the sealing wafer is formed of a glass having a thermal expansion coefficient of 3.2×10⁻⁶/° C. The MEMS element forming substrate as the semiconductor wafer is formed of silicon having a thermal expansion coefficient of 24×10⁻⁶/° C. Accordingly, there is a large mismatch of the thermal expansion coefficients between the MEMS element forming substrate and the sealing cap substrate.

According to Patent Reference, after the semiconductor wafer is bonded with the sealing wafer with the anodic bonding method, the semiconductor wafer and the sealing wafer are cooled down from a high temperature to an ordinary atmospheric temperature. During the cooling process, the semiconductor wafer and the sealing wafer contract. As described above, the semiconductor wafer formed of silicon has the thermal expansion coefficient greater than that of the sealing wafer formed of a glass. Accordingly, the semiconductor wafer generates a tensional force against the sealing wafer.

Further, when the semiconductor wafer is bonded with the sealing wafer with the anodic bonding method, the semiconductor wafer is strongly and chemically bonded with the sealing wafer. Accordingly, when the semiconductor wafer generates a tensional force against the sealing wafer, the tensional force is directly transmitted to the sealing wafer.

FIGS. 20(a) and 20(b) are schematic sectional views showing a semiconductor wafer 5 and a sealing wafer 30 of a conventional semiconductor device. When the sealing wafer 30 receives a tensional force from the semiconductor wafer 5, the sealing wafer 30 contracts to a larger extent than an inherent contraction due to the thermal expansion coefficient thereof.

As shown in FIG. 20(a), the sealing wafer 30 as the sealing cap substrate may be bent in an opposite direction. Further, as shown in FIG. 20(b), when the sealing wafer 30 is bent, the sealing wafer 30 may be broken, thereby lowering yield. Note that arrows in FIG. 20(a) indicate a direction that the sealing wafer 30 as the sealing cap substrate receives the tensional force from the semiconductor wafer 5 as the MEMS element forming substrate.

In Patent Reference described above, the semiconductor wafer formed of silicon has the thermal expansion coefficient greater than that of the sealing wafer formed of glass, thereby causing the problem described above. On the other hand, when a semiconductor wafer has a thermal expansion coefficient smaller than that of a sealing wafer, the semiconductor wafer may be bent, thereby causing a similar problem.

In view of the problems described above, an object of the present invention is to provide a semiconductor device and a method of producing the semiconductor device capable of solving the problems of the conventional semiconductor device occurred when a semiconductor wafer is bonded with a sealing wafer, thereby improving yield.

Further objects and advantages of the invention will be apparent from the following description of the invention.

### SUMMARY OF THE INVENTION

In order to attain the objects described above, according to a first aspect of the present invention, a method of producing a semiconductor device includes the steps of: preparing a semiconductor wafer having an MEMS (Micro Electro Mechanical Systems) element formed on a surface thereof; forming a groove portion surrounding the MEMS element in the surface of the semiconductor wafer; preparing a sealing wafer having a recess portion formed in a surface thereof and a protruding portion surrounding the recess portion; filling an adhesive in the groove portion; arranging the semiconductor wafer so that the surface of the semiconductor wafer faces the surface of the sealing wafer; fitting the protruding portion into the groove portion so that the recess portion covers the MEMS element; hardening the adhesive to form an MEMS element mounting wafer; and cutting the MEMS element mounting wafer into pieces. Further, the adhesive is formed of a silicone type resin.

According to a second aspect of the present invention, a semiconductor device includes a semiconductor chip having an MEMS element on a surface thereof and a step portion surrounding the MEMS element; and a sealing cap bonded to the step portion with an adhesive and arranged to cover the MEMS element. Further, the step portion includes a bottom surface and a side surface, so that the bottom surface and the side surface of the step portion are bonded to the sealing cap. Further, the adhesive is formed of a silicone type resin.

In the first aspect of the present invention, when the semiconductor wafer is bonded to the sealing wafer, it is possible to alleviate a thermal stress applied from the semiconductor wafer to the sealing wafer due to a difference in thermal expansion coefficients, thereby improving yield of the semiconductor device.

In the second aspect of the present invention, when an environmental temperature changes, it is possible to alleviate a thermal stress applied from the semiconductor wafer to the sealing wafer.

When the semiconductor wafer has a thermal expansion coefficient smaller than that of the sealing wafer, the semiconductor wafer may be bent, thereby causing a problem. Even in this case, with the semiconductor device of the present invention, it is possible to alleviate a thermal stress applied from the sealing wafer to the semiconductor wafer.

According to a third aspect of the present invention, a semiconductor device includes a semiconductor chip having an MEMS element on a surface thereof and a step portion surrounding the MEMS element. The step portion includes a bottom surface and a side surface. The semiconductor device further includes a sealing cap bonded to the bottom surface and the side surface of the step portion with an adhesive and arranged to cover the MEMS element. The adhesive is formed of a silicone type resin.

In the semiconductor device according to the third aspect, the step portion may have a recess shape.

In the semiconductor device according to the third aspect, the step portion may have an undulation pattern formed in a bottom surface thereof.

In the semiconductor device according to the third aspect, the step portion may have an undulation pattern having a tip portion with a pointed shape.

In the semiconductor device according to the third aspect, the step portion may have an undulation pattern having a tip portion with a curved shape.

In the semiconductor device according to the third aspect, a buffer layer may be formed on the bottom surface of the step portion so that the sealing cap is bonded to the bottom surface of the step portion through the buffer layer.

In the semiconductor device according to the third aspect, the buffer layer may be formed of one of an epoxy type resin and a polyimide type resin.

In the semiconductor device according to the third aspect, the buffer layer may be formed of a silicone type resin.

In the semiconductor device according to the third aspect, the adhesive may be disposed away from the MEMS element.

### BRIEF DESCRIPTION OF THE DRAWINGS

FIG. 1 is a schematic plan view No. 1 showing a method of producing a semiconductor device according to a first embodiment of the present invention;

FIG. 2 is a schematic sectional view No. 1 showing the method of producing the semiconductor device taken along a line 2-2 in FIG. 1 according to the first embodiment of the present invention;

FIGS. 3(a) and 3(b) are schematic sectional views No. 2 showing the method of producing the semiconductor device according to the first embodiment of the present invention;

FIGS. 4(a) and 4(b) are schematic sectional views No. 3 showing the method of producing the semiconductor device according to the first embodiment of the present invention;

FIGS. 5(a) and 5(b) are schematic plan views No. 2 showing the method of producing the semiconductor device according to the first embodiment of the present invention;

FIGS. 6(a) and 6(b) are schematic sectional views No. 4 showing the method of producing the semiconductor device taken along a line 6-6 in FIG. 5 according to the first embodiment of the present invention;

FIGS. 7(a) and 7(b) are schematic sectional views No. 5 showing the method of producing the semiconductor device taken along the line 6-6 in FIG. 5 according to the first embodiment of the present invention;

FIGS. 8(a) to 8(d) are schematic sectional views No. 6 showing the method of producing the semiconductor device according to the first embodiment of the present invention;

FIG. 9(a) is a schematic plan view No. 3 showing the method of producing the semiconductor device according to the first embodiment of the present invention;

FIG. 9(b) is a schematic sectional view No. 7 showing the method of producing the semiconductor device taken along a line 9(b)-9(b) in FIG. 9(a) according to the first embodiment of the present invention;

FIG. 10(a) is a schematic sectional view No. 8 showing the method of producing the semiconductor device taken along the line 9(b)-9(b) in FIG. 9(a) according to the first embodiment of the present invention;

FIG. 10(b) is a schematic plan view No. 4 showing the method of producing the semiconductor device according to the first embodiment of the present invention;

FIG. 11(a) is a schematic sectional view No. 9 showing the method of producing the semiconductor device taken along the line 9(b)-9(b) in FIG. 9(a) according to the first embodiment of the present invention;

FIG. 11(b) is a schematic plan view No. 5 showing the method of producing the semiconductor device according to the first embodiment of the present invention;

FIGS. 12(a) and 12(b) are schematic sectional views No. 10 showing the method of producing the semiconductor device according to the first embodiment of the present invention;

FIG. 13(a) is a schematic plan view No. 6 showing the method of producing the semiconductor device according to the first embodiment of the present invention;

FIG. 13(b) is a schematic sectional view No. 11 showing the method of producing the semiconductor device according to the first embodiment of the present invention;

FIG. 14(a) is a schematic plan view No. 7 showing the method of producing the semiconductor device according to the first embodiment of the present invention;

FIG. 14(b) is a schematic sectional view No. 12 showing the method of producing the semiconductor device taken along a line 14(b)-14(b) in FIG. 14(a) according to the first embodiment of the present invention;

FIG. 15 is a schematic plan view No. 1 showing a method of producing a semiconductor device according to a second embodiment of the present invention;

FIG. 16 is a schematic plan view No. 2 showing the method of producing the semiconductor device according to the second embodiment of the present invention;

FIG. 17(a) is a schematic plan view No. 3 showing the method of producing the semiconductor device according to the second embodiment of the present invention;

FIG. 17(b) is a schematic sectional view No. 1 showing the method of producing the semiconductor device taken along a line 17(b)-17(b) in FIG. 16 and FIG. 17(a) according to the second embodiment of the present invention;

FIG. 18(a) is a schematic plan view No. 4 showing the method of producing the semiconductor device according to the second embodiment of the present invention;

FIG. 18(b) is a schematic sectional view No. 2 showing the method of producing the semiconductor device taken along a line 18(b)-18(b) in FIG. 18(a) according to the second embodiment of the present invention;

FIG. 19(a) is a schematic plan view No. 5 showing the method of producing the semiconductor device according to the second embodiment of the present invention;

FIG. 19(b) is a schematic sectional view No. 3 showing the method of producing the semiconductor device taken along a line 19(b)-19(b) in FIG. 19(a) according to the second embodiment of the present invention; and

FIGS. 20(a) and 20(b) are schematic sectional views showing a semiconductor wafer and a sealing wafer of a conventional semiconductor device.

### DETAILED DESCRIPTION OF PREFERRED EMBODIMENTS

Hereunder, preferred embodiments of the present invention will be explained with reference to the accompanying drawings.

### First Embodiment

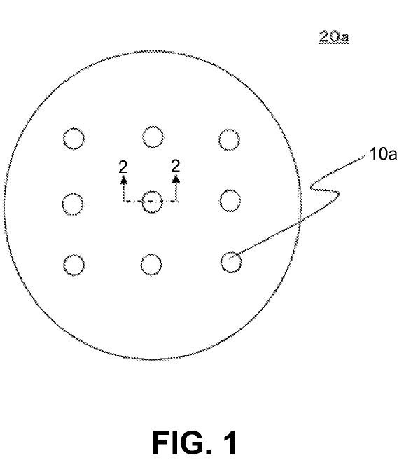

A first embodiment of the present invention will be explained with reference to FIGS. 1 to 13(a)-13(b).

In the embodiment, a method of producing a semiconductor device 90 includes the steps of: preparing a semiconductor wafer 20a having a plurality of switch element structures 10a as MEMS (Micro Electro Mechanical Systems) elements formed on a surface thereof; forming a groove portion 30a surrounding each of the switch element structures 10a in a surface of the semiconductor wafer 20a; preparing a sealing wafer 60a having a plurality of recess portions 40a formed in a surface thereof and a protruding portion 50a surrounding each of the recess portions 40a; filling an adhesive 70a in the groove portion 30a; arranging the semiconductor wafer 20a so that the surface of the semiconductor wafer 20a faces the surface of the sealing wafer 60a; fitting the protruding portion 50a into the groove portion 30a so that the recess portions 40a cover the switch element structures 10a; hardening the adhesive 70a to form an MEMS element mounting wafer 80; and cutting the MEMS element mounting wafer 80 into pieces. Further, the adhesive 70a is formed of a silicone type resin. The groove portion 30a is formed in the surface of the semiconductor wafer 20a in a lattice pattern.

FIG. 1 is a schematic plan view No. 1 showing the method of producing the semiconductor device 90 according to the first embodiment of the present invention.

In the first step, the semiconductor wafer 20a is prepared. As shown in FIG. 1, a plurality of the switch element structures 10a is formed on the surface of the semiconductor wafer 20a. In FIG. 1, each of the switch element structures 10a is represented with a simple circle.

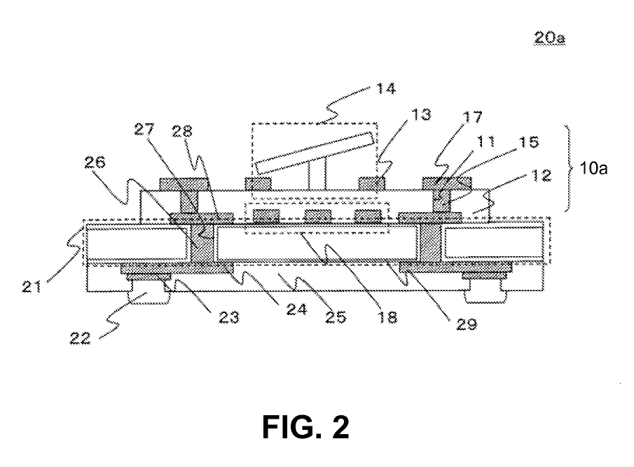

The semiconductor wafer 20a will be explained in more detail next with reference to FIG. 2. FIG. 2 is a schematic sectional view No. 1 showing the method of producing the semiconductor device 90 taken along a line 2-2 in FIG. 1 according to the first embodiment of the present invention.

As shown in FIG. 2, the semiconductor wafer 20a includes a silicon wafer 21; outer connection terminals 22; outer connection pads 23; lower wiring portions 24; a backside protection layer 25; through electrodes 26; through holes 27; upper wiring portions 28; and insulating films 29. The silicon wafer 21 has a thickness of, for example, 600 μm.

The silicon wafer 21 will be explained in more detail next. The insulating films 29 are disposed on entire areas of a front surface and a backside surface of the silicon wafer 21. The lower wiring portions 24 are formed of aluminum and the likes, and are disposed on the backside surface of the silicon wafer 21. The backside protection layer 25 is formed of a polyimide type resin and the likes, and is disposed to cover an entire area of the backside surface of the silicon wafer 21 and the lower wiring portions 24.

In the embodiment, the outer connection terminals 22 are formed of gold and the likes, and are disposed on the backside surface of the silicon wafer 21. Further, the outer connection terminals 22 are exposed from the backside protection layer 25. The lower wiring portions 24 are formed of copper and the likes, and are electrically connected to the outer connection terminals 22 through the outer connection pads 23.

The insulating films 29 are disposed on sidewalls of the through holes 27, and the through holes 27 are formed in the silicon wafer 21. The through electrodes 26 are formed of copper and the likes, and are filled in the through holes 27. The lower wiring portions 24 are electrically connected to the through electrodes 26. The upper wiring portions 28 are formed of aluminum and the likes, and are disposed on the surface of the silicon wafer 21. Further, the upper wiring portions 28 are electrically connected to the through electrodes 26.

In the embodiment, each of the switch element structures 10a includes through holes 11; a protection layer 12; electrodes 13; a switch element 14 having a movable portion; through electrodes 15; uppermost wiring portions 17; and coils 18.

In the embodiment, the protection layer 12 is formed of a nitride film and the likes, and is disposed on the surface of the silicon wafer 21 with the insulating films 29 in between. The through holes 11 are formed in the protection layer 12, and the through electrodes 15 formed of copper and the likes are embedded in the through holes 11. The uppermost wiring portions 17 are disposed on a surface of the protection layer 12, and are electrically connected to the upper wiring portions 28 through the through electrodes 15. The coils 18 having a plate shape are disposed inside the protection layer 12 and on the surface of the silicon wafer 21 with the insulating films 29 in between. The switch element 14 is disposed on the surface of the silicon wafer 21, and has the movable portion as a cantilever with a pivot. The electrodes 13 are disposed on the protection layer 12 at end portions of the movable portion of the switch element 14.

In the embodiment, the movable portion of the switch element 14 is formed of a magnetic alloy, so that drive energy is supplied to the movable portion of the switch element 14 through an effect of the coils 18. When the movable portion is inclined and contacts with the electrode 13, a switch circuit is turned on. A signal (on or off) of the switch circuit is transmitted to the uppermost wiring portions 17, so that the signal is output externally through the through electrodes 15, the upper wiring portions 28, the through electrodes 26, the lower wiring portions 24, the outer connection pads 23, and the outer connection terminals 22.

In the next step, the groove portion 30a is formed in the surface of the semiconductor wafer 20a. In the embodiment, the groove portion 30a is formed in a lattice pattern to surround each of the switch element structures 10a.

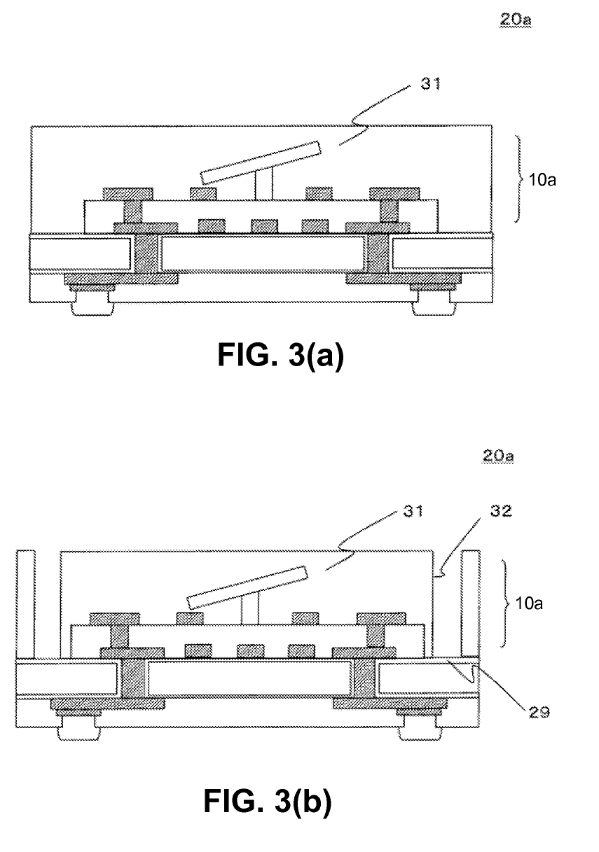

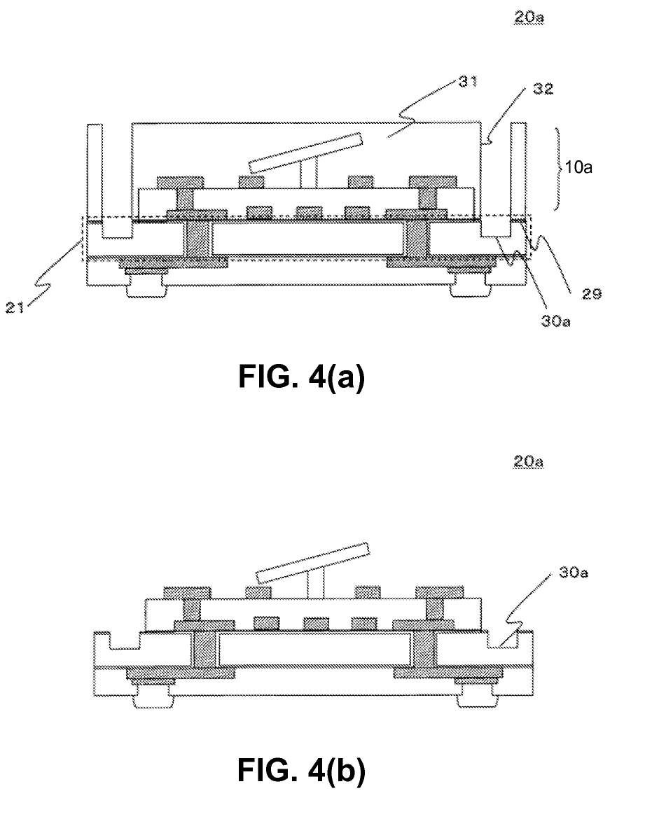

A method of forming the groove portion 30a will be explained with reference to FIGS. 3(a)-3(b) to 4(a)-4(b). FIGS. 3(a) and 3(b) are schematic sectional views No. 2 showing the method of producing the semiconductor device 90 according to the first embodiment of the present invention. FIGS. 4(a) and 4(b) are schematic sectional views No. 3 showing the method of producing the semiconductor device 90 according to the first embodiment of the present invention.

First, as shown in FIG. 3(a), a resist film 31 is formed on an entire surface of the semiconductor wafer 20a through, for example, spin coating, so that the resist film 31 covers the switch element structure 10a. In the next step, as shown in FIG. 3(b), an exposure/developing process is applied to the resist film 31 in a forming area of the groove portion 30a, i.e., an area surrounding the switch element structure 10a, thereby forming an opening portion 32 and exposing a part of the insulating films 29. The opening portion 32 has a width of, for example, 250 μm in a direction of the line 2-2.

In the next step, as shown in FIG. 4(a), the insulating films 29 thus exposed is removed through dry etching to expose a part of the silicon wafer 21. Then, the part of the silicon wafer 21 thus exposed is removed through dry etching. As a result, the groove portion 30a has a depth of, for example, 150 μm. In the last step, the resist film 31 is removed, thereby forming the groove portion 30a having a bottom surface and side surfaces as shown in FIG. 4(b).

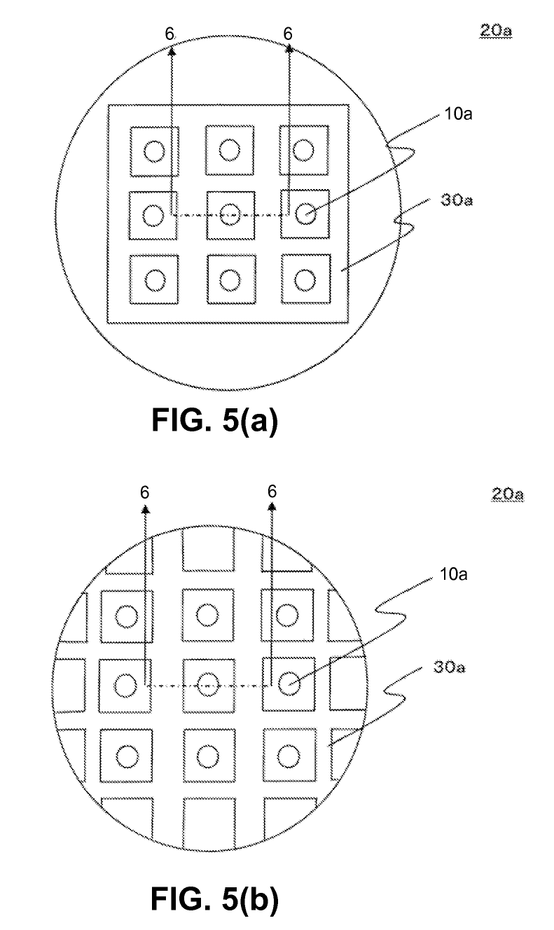

FIGS. 5(a) and 5(b) are schematic plan views No. 2 showing the method of producing the semiconductor device 90 according to the first embodiment of the present invention. Through the process described above, as shown in FIG. 5(a), the groove portion 30a is formed in the surface of the semiconductor wafer 20a in the lattice pattern surrounding the switch element structures 10a.

In the embodiment, the groove portion 30a may be formed through a process other than the process described above. For example, the groove portion 30a may be formed using a dicing blade. When the groove portion 30a is formed using a dicing blade, the dicing blade is set along a direction perpendicular to the surface of the semiconductor wafer 20a. Then, the semiconductor wafer 20a is cut with the dicing blade in lateral and vertical directions thereof along an area other than forming areas of the switch element structures 10a.

In the case of forming the groove portion 30a using the dicing blade, as opposed to the case of forming the groove portion 30a through dry etching, it is not necessary to use a special mask, thereby making it possible to reduce a manufacturing cost. When the groove portion 30a is formed using the dicing blade, the groove portion 30a reaches an edge of the semiconductor wafer 20a as shown in FIG. 5(a).

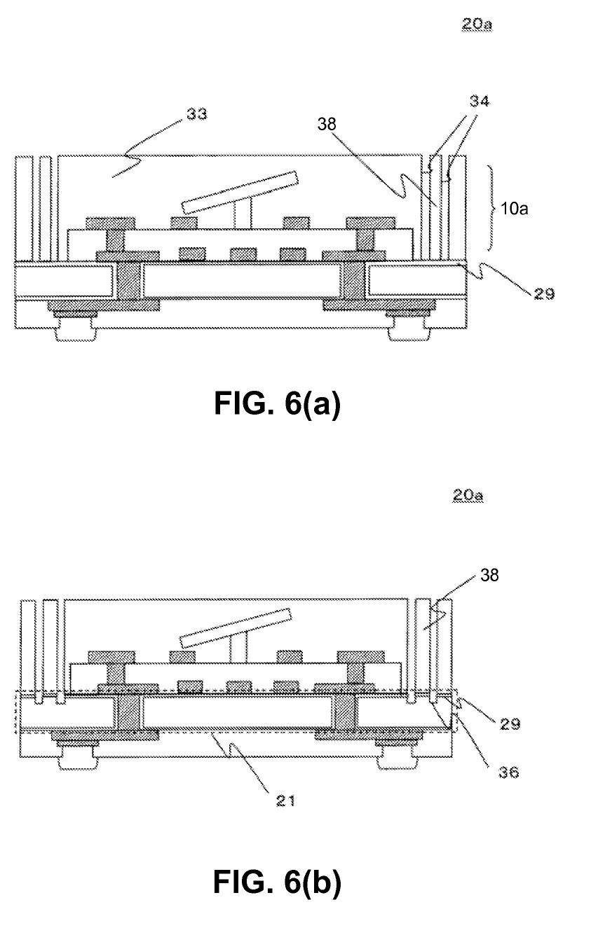

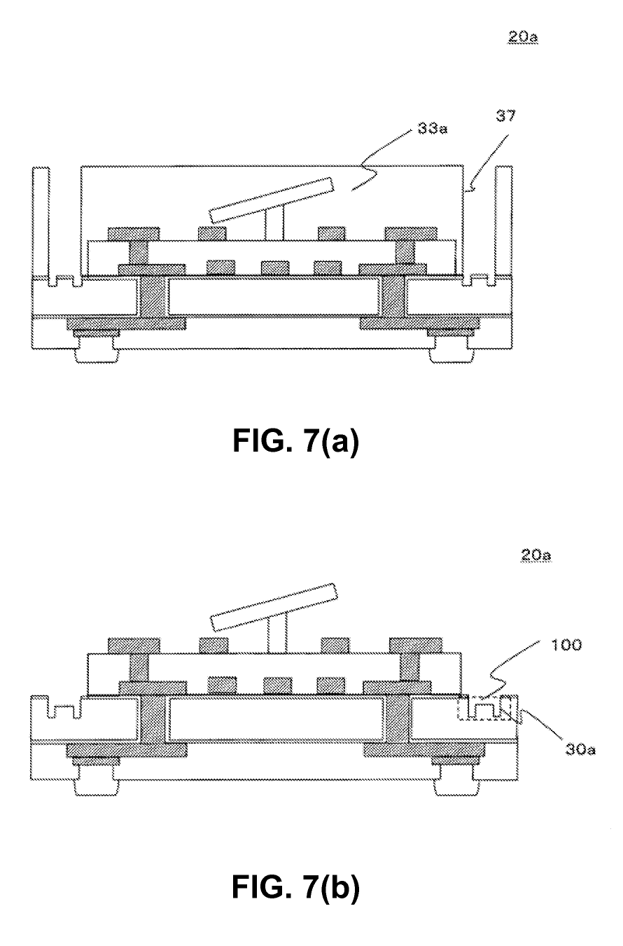

In the embodiment, when the groove portion 30a is formed, an undulation pattern 100 may be formed in the bottom surface of the groove portion 30a. A method of forming the undulation pattern 100 will be explained next with reference to FIGS. 6(a)-6(b) and 7(a)-7(b).

FIGS. 6(a) and 6(b) are schematic sectional views No. 4 showing the method of producing the semiconductor device 90 taken along a line 6-6 in FIG. 5 according to the first embodiment of the present invention. FIGS. 7(a) and 7(b) are schematic sectional views No. 5 showing the method of producing the semiconductor device 90 taken along the line 6-6 in FIG. 5 according to the first embodiment of the present invention.

In this case, first, similar to the process shown in FIG. 3(a), the resist film 33 is formed on the entire surface of the semiconductor wafer 20a through, for example, spin coating, so that the resist film 33 covers the switch element structure 10a. In the next step, as shown in FIG. 6(a), an exposure/developing process is applied to the resist film 33 in a forming area of the undulation pattern 100, thereby forming opening portions 34 and exposing a part of the insulating films 29. The opening portions 34 have a width of, for example, 25 μm with an interval (the resist film 33) of 200 μm in the direction of the line 2-2. Note that the resist film 33 between the opening portions 34 is referred to as an intermediate resist film 38.

In the next step, as shown in FIG. 6(b), the insulating film 29 thus exposed is removed through dry etching to expose a part of the silicon wafer 21. Then, the part of the silicon wafer 21 thus exposed is removed through dry etching, thereby forming opening groove portions 36. The opening groove portions 36 have a depth of, for example, 50 μm.

In the next step, as shown in FIG. 7(a), after the resist film 33 is temporarily removed, a resist film 33a is formed on the surface of the semiconductor wafer 20a one more time. Afterward, an exposure/developing process is applied to the resist film 33a to remove a part of the resist film 33a corresponding to the groove portion 30a, thereby forming an opening groove portion 37.

In the next step, as shown in FIG. 7(b), the resist film 33 is removed through dry etching applied to the opening groove portion 37, thereby forming the groove portion 30a having the undulation pattern 100 in the bottom surface thereof. The dry etching is applied to the opening groove portion 37, so that the opening groove portion 37 has a depth of 150 μm.

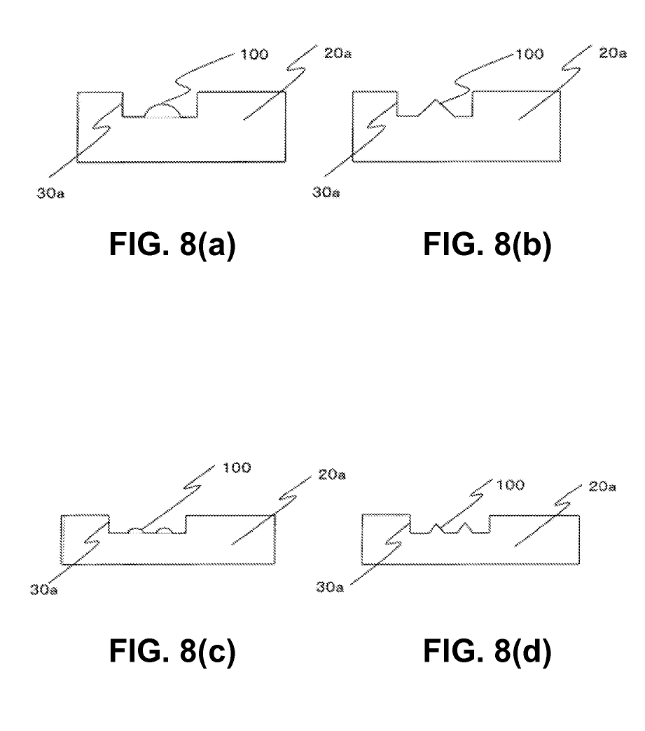

In the embodiment, as shown in FIG. 7(b), the undulation pattern 100 has a flat top portion, and may have other shapes. FIGS. 8(a) to 8(d) are schematic sectional views No. 6 showing the method of producing the semiconductor device 90 according to the first embodiment of the present invention.

As shown in FIG. 8(a), the undulation pattern 100 preferably has a curved top portion. Alternatively, as shown in FIG. 8(b), the undulation pattern 100 may have a pointed top portion. Further, as shown in FIGS. 8(c) and 8(d), the undulation pattern 100 may have multiple protruded top portions.

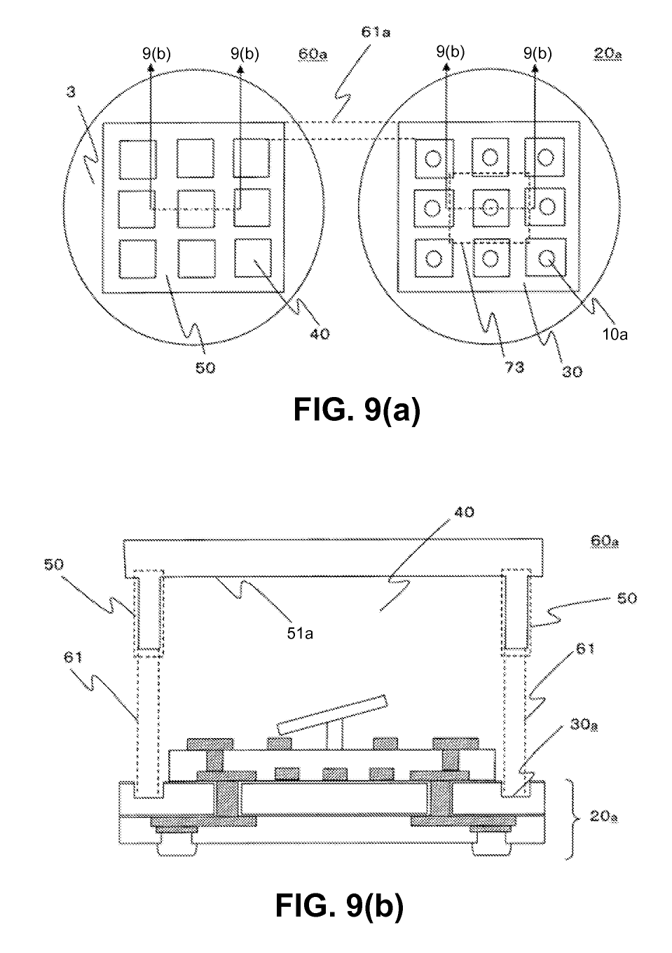

A method of preparing the sealing wafer 60a will be explained next with reference to FIGS. 9(a) and 9(b). FIG. 9(a) is a schematic plan view No. 3 showing the method of producing the semiconductor device 90 according to the first embodiment of the present invention. FIG. 9(b) is a schematic sectional view No. 7 showing the method of producing the semiconductor device 90 taken along a line 9(b)-9(b) in FIG. 9(a) according to the first embodiment of the present invention.

As shown in FIG. 9(a), the sealing wafer 60a includes a plurality of the recess portions 40a formed in the surface thereof, and the protruding portion 50a surrounding the recess portions 40a. The sealing wafer 60a is formed of, for example, a glass.

In the embodiment, a plurality of the recess portions 40a is formed in the surface of the sealing wafer 60a. Each of the recess portions 40a has a sufficient area and a sufficient depth to cover the switch element structure 10a when the surface of the semiconductor wafer 20a faces the surface of the sealing wafer 60a.

In the embodiment, the protruding portion 50a is disposed to surround the recess portions 40a. More specifically, the protruding portion 50a protrudes from the surface of the sealing wafer 60a, and has a lattice shape. Further, the protruding portion 50a is arranged in an area corresponding to the groove portion 30a as indicated with lines 61a in FIG. 9(a) when the surface of the semiconductor wafer 20a faces a surface 3 of the sealing wafer 60a. The protruding portion 50a has a width of, for example, 200 μm in a direction of the line 9(b)-9(b) smaller than the width of the groove portion 30a in the direction of the line 6-6, so that the protruding portion 50a is fitted in the groove portion 30a. Note that each of the recess portions 40a has a bottom surface as a ceiling portion 51a.

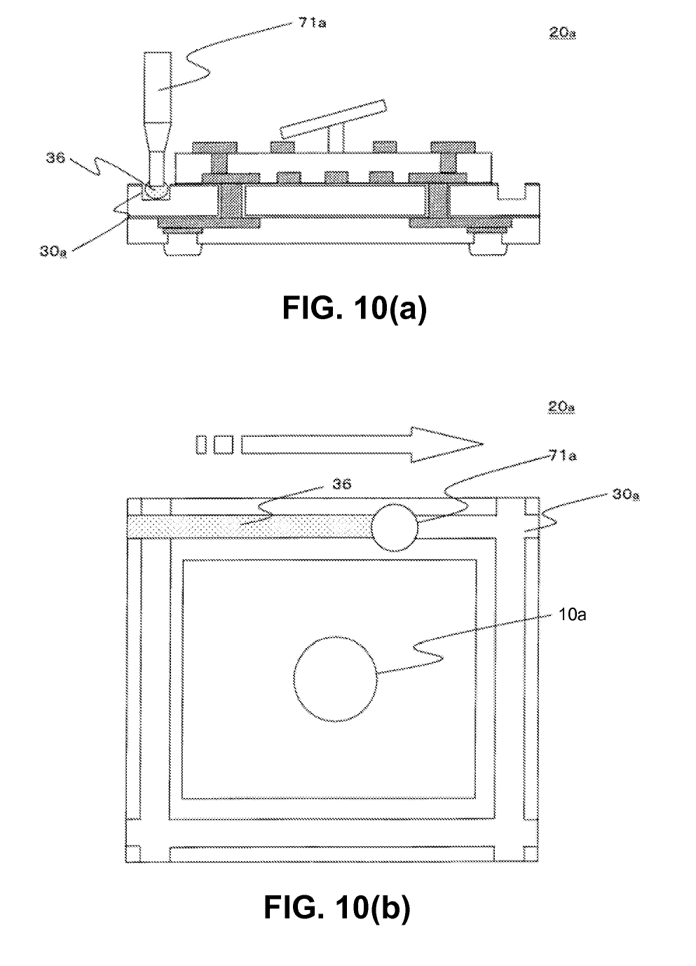

In the embodiment, it is preferred that a buffer layer 35 is formed on the bottom surface of the groove portion 30a. FIG. 10(a) is a schematic sectional view No. 8 showing the method of producing the semiconductor device 90 taken along the line 9(b)-9(b) in FIG. 9(a) according to the first embodiment of the present invention. FIG. 10(b) is a schematic plan view No. 4 showing the method of producing the semiconductor device 90 according to the first embodiment of the present invention. FIG. 10(b) is an enlarged view of an area 73 shown in FIG. 9(a). In FIG. 10(b), the switch element structure 10a is represented with a simple circle.

As shown in FIG. 10(a), first, a resin 36 such as an epoxy type resin or a polyimide type resin is filled in the groove portion 30a with a dispensing method. More specifically, a dispenser 71a is set perpendicularly relative to the semiconductor wafer 20a. Then, as shown in FIG. 10(b), while the dispenser 71a moves along the groove portion 30a, the resin 36 is injected into the groove portion 30a. After the resin 36 is filled in the groove portion 30a, the resin 36 is hardened, thereby forming the buffer layer 35. Note that the resin 36 may be partially filled in the groove portion 30a.

In the embodiment, it is preferred that the buffer layer 35, i.e., the resin 36 thus hardened, has a Young's modulus smaller than that of at least one of the semiconductor wafer 20a and the sealing wafer 60a. Further, the buffer layer 35 is formed of the epoxy type resin or the polyimide type resin, and is not limited thereto. It is preferred that the buffer layer 35 is formed of a silicone type resin such as a silicone rubber (described later).

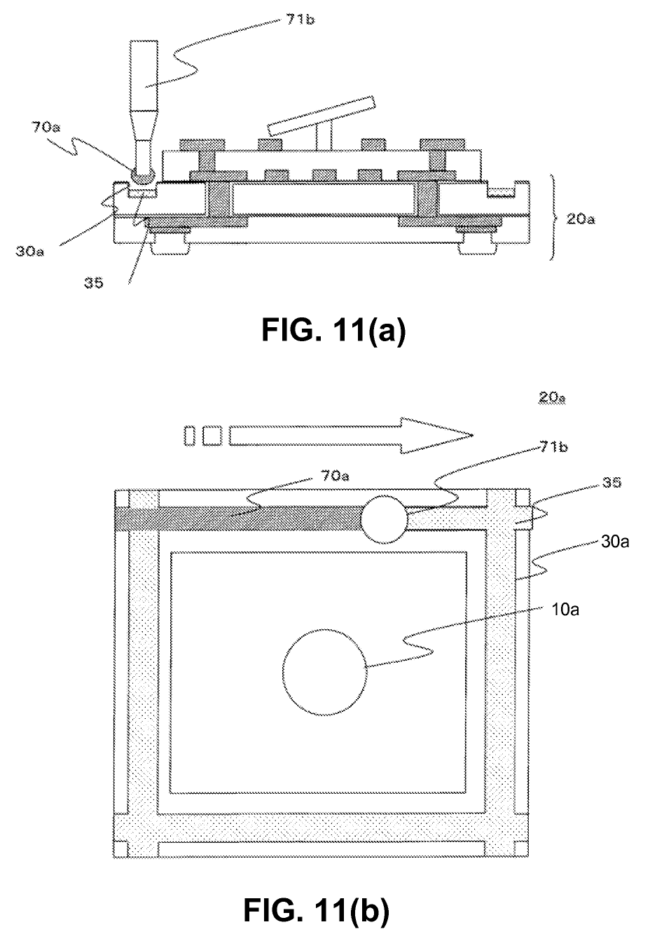

In the next step, the adhesive 70a is filled in the groove portion 30a. FIG. 11(a) is a schematic sectional view No. 9 showing the method of producing the semiconductor device 90 taken along the line 9(b)-9(b) in FIG. 9(a) according to the first embodiment of the present invention. FIG. 11(b) is a schematic plan view No. 5 showing the method of producing the semiconductor device 90 according to the first embodiment of the present invention. FIG. 11(b) is an enlarged view of the area 73 shown in FIG. 9(a). In FIG. 11(b), the switch element structure 10a is represented with a simple circle.

As shown in FIG. 11(a), first, the adhesive 70a is filled in the groove portion 30a with a dispensing method. More specifically, the dispenser 71a is set perpendicularly relative to the semiconductor wafer 20a. Then, as shown in FIG. 11(b), while the dispenser 71a moves along the groove portion 30a, the adhesive 70a is injected into the groove portion 30a. It is preferred that the adhesive 70a is filled in the groove portion 30a such that the adhesive 70a does not overflow in an area other than the groove portion 30a after the adhesive 70a is hardened (for a reason described later).

When the adhesive 70a overflows out of the groove portion 30a and is attached to the switch element structures 10a, the switch element 14 may malfunction. When the groove portion 30a is not provided, it is necessary to apply the adhesive 70a in a small amount, thereby preventing the adhesive 70a from overflowing to the switch element structures 10a. In this case, only a small amount of the adhesive 70a is applied to bond the semiconductor wafer 20a to the sealing wafer 60a. Accordingly, it is difficult to securely bond the semiconductor wafer 20a to the sealing wafer 60a, and the adhesive 70a may be cracked after the semiconductor wafer 20a is bonded to the sealing wafer 60a, thereby making it difficult to produce the semiconductor device 90 with high reliability. For the reason described above, it is imperative to provide the groove portion 30a.

In the embodiment, it is preferred that the adhesive 70a has a Young's modulus smaller than that of at least one of the semiconductor wafer 20a and the sealing wafer 60a. Further, It is preferred that the adhesive 70a is formed of a silicone type resin such as a silicone rubber (for a reason described later).

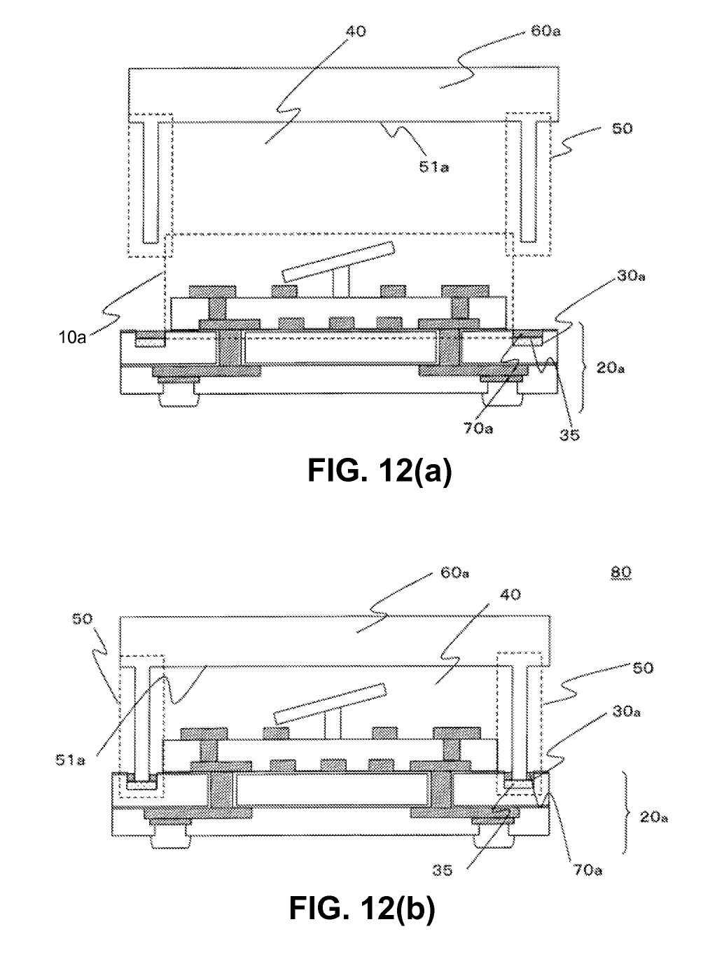

FIGS. 12(a) and 12(b) are schematic sectional views No. 10 showing the method of producing the semiconductor device 90 according to the first embodiment of the present invention.

In the next step, as shown in FIG. 12(a), the surface of the semiconductor wafer 20a faces the surface of the sealing wafer 60a, and the protruding portion 50a is fitted into the groove portion 30a, so that the recess portions 40a cover the switch element structures 10a. In this step, the protruding portion 50a is fitted into the groove portion 30a, thereby making it easy to position the recess portions 40a relative to the switch element structures 10a.

When the protruding portion 50a is fitted into the groove portion 30a, it is preferred that the sealing wafer 60a is pressed against the semiconductor wafer 20a, so that it is possible to reduce an amount of the adhesive 70a at an interface between the protruding portion 50a and the bottom surface of the groove portion 30a as much as possible. When the sealing wafer 60a is pressed against the semiconductor wafer 20a, it is possible to accurately control a thickness of the adhesive 70a. Accordingly, it is possible to obtain a desirable distance between the ceiling portions 51a and the switch element structures 10a simply through adjusting a vertical length of the protruding portion 50a with respect to the surface of the semiconductor wafer 20a.

As described above, in the embodiment, it is preferred that the adhesive 70a has a Young's modulus smaller than those of the semiconductor wafer 20a and the sealing wafer 60a. Further, it is preferred that the adhesive 70a is formed of a silicone type resin. The reason will be explained next.

When the adhesive 70a is hardened, a thermal process is applied. In the thermal process, the semiconductor wafer 20a and the sealing wafer 60a expand according to thermal expansion coefficients thereof. After the thermal process, the semiconductor wafer 20a and the sealing wafer 60a contract.

In the embodiment, the sealing wafer 60a is formed of a glass having a thermal expansion coefficient of 3.2×10⁻⁶/° C., and the semiconductor wafer 20a is formed of silicon having a thermal expansion coefficient of 24×10⁻⁶/° C. significantly different from that of the sealing wafer 60a. Accordingly, after the adhesive 70a is hardened through the thermal process, the semiconductor wafer 20a contracts to a larger extent than the sealing wafer 60a due to the thermal expansion coefficient of the semiconductor wafer 20a larger than that of the sealing wafer 60a. As a result, the semiconductor wafer 20a generates a tensional force with respect to the sealing wafer 60a formed of a glass.

If the adhesive 70a has a Young's modulus similar to those of the semiconductor wafer 20a and the sealing wafer 60a after the thermal process, or the sealing wafer 60a is bonded to the semiconductor wafer 20a with the anodic bonding method, the sealing wafer 60a is strongly bonded to the semiconductor wafer 20a. Accordingly, the tensional force applied from the semiconductor wafer 20a to the sealing wafer 60a is directly transmitted to the sealing wafer 60a. When the sealing wafer 60a receives the tensional force from the semiconductor wafer 20a, the sealing wafer 60a tends to contract to a larger extend than that the sealing wafer 60a inherently contracts due to the thermal expansion coefficient thereof.

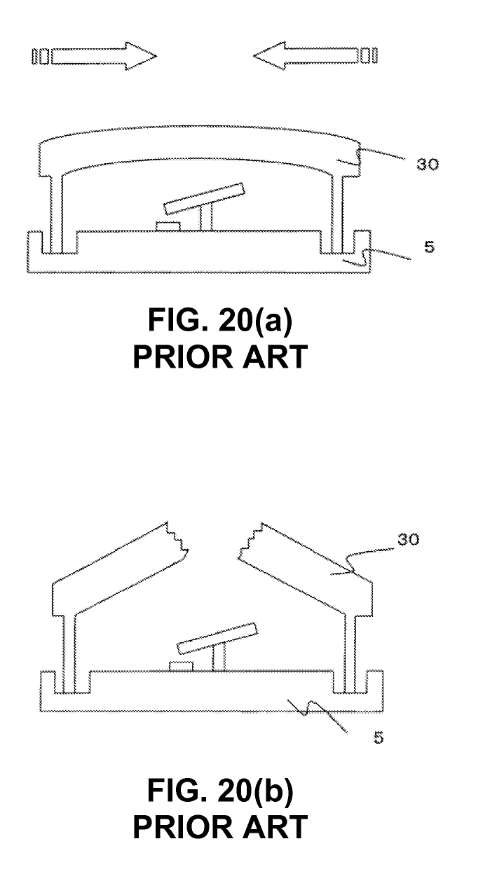

In the case described above, as shown in FIG. 20(a), the sealing wafer 60a may be bent in an opposite direction relative to the semiconductor wafer 20a. Further, as shown in FIG. 20(b), when the sealing wafer 60a is bent excessively, the sealing wafer 60a may be broken, thereby lowering yield. Note that arrows in FIG. 20(a) indicate a direction that the sealing wafer 60a receives the tensional force from the semiconductor wafer 20a.

As described above, in the embodiment, the adhesive 70a has a Young's modulus sufficiently smaller than those of the semiconductor wafer 20a and the sealing wafer 60a. Accordingly, the adhesive 70a tends to deform more freely due to the smaller Young's modulus, thereby making it possible to alleviate the tensional force applied from the semiconductor wafer 20a to the sealing wafer 60a.

In general, a glass has a Young's modulus of 65 to 95 MPa, and silicon has a Young's modulus of 160 to 190 MPa. On the other hand, a silicone type resin has a Young's modulus of 0.5 to 20 MPa sufficiently smaller than that of a glass or silicon. Accordingly, the adhesive 70a tends to deform more freely due to the smaller Young's modulus, thereby making it possible to alleviate the tensional force applied from the semiconductor wafer 20a to the sealing wafer 60a.

As described above, in the embodiment, it is preferred that the adhesive 70a has a Young's modulus smaller than those of the semiconductor wafer 20a and the sealing wafer 60a. Further, it is preferred that the adhesive 70a is formed of a silicone type resin.

In the embodiment, the semiconductor wafer 20a formed of silicon has the thermal expansion coefficient greater than that of the sealing wafer 60a formed of a glass. On the other hand, when the semiconductor wafer 20a has a thermal expansion coefficient smaller than that of the sealing wafer 60a, the semiconductor wafer 60a may be bent. In this case, the embodiment still provides the same effect described above.

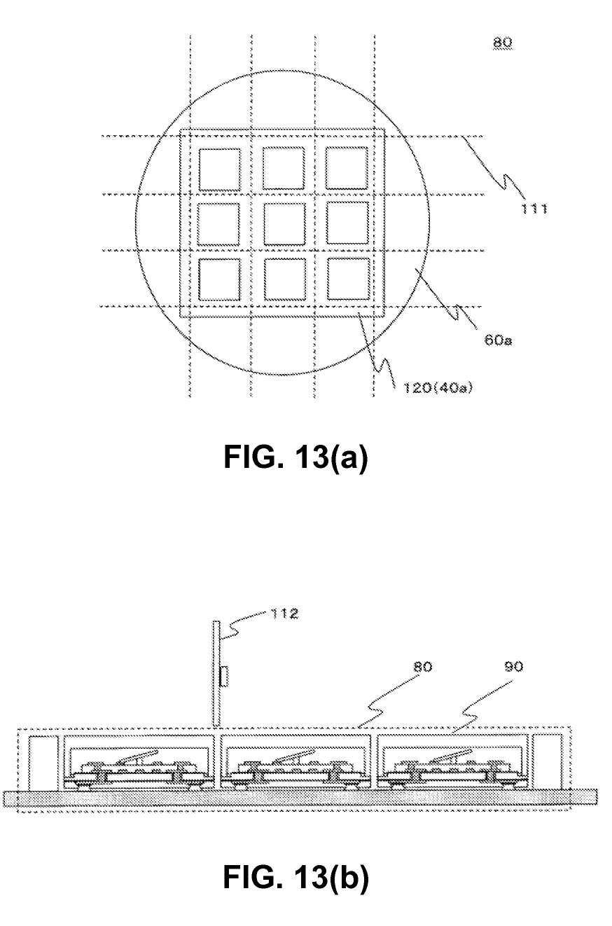

Through the process described above, the MEMS element mounting wafer 80 is completed as shown in FIG. 12(b). In the last step, the MEMS element mounting wafer 80 is cut into pieces, thereby forming the semiconductor devices 90. FIG. 13(a) is a schematic plan view No. 6 showing the method of producing the semiconductor device 90 according to the first embodiment of the present invention. FIG. 13(b) is a schematic sectional view No. 11 showing the method of producing the semiconductor device 90 according to the first embodiment of the present invention.

As shown in FIG. 13(a), a dicing blade 112 cuts the MEMS element mounting wafer 80 along hidden lines 111 in the area where the protruding portion 50a is formed, such that the dicing blade 112 does not reach the sidewalls of the protruding portion 50a in a plan view of the sealing wafer 60a viewed from the front side thereof. Alternatively, a laser dicing method may be adopted to cut the MEMS element mounting wafer 80 in pieces. After the last step, the semiconductor device 90 is completed.

A configuration of the semiconductor device 90 will be explained in more detail next.

In the embodiment, the semiconductor device 90 includes a semiconductor chip 20b and a sealing cap 60b. The switch element structure 10a as an MEMS element and a step portion 30b surrounding the switch element structure 10a are formed on the surface of the semiconductor chip 20b. The sealing cap 60b is attached to the step portion 30b with the adhesive 70a, so that the sealing cap 60b covers the switch element structure 10a. Further, the step portion 30b includes a bottom surface and side surfaces, so that the bottom surface and the side surfaces of the step portion 30b are bonded to the sealing cap 60b. The adhesive 70a is formed of a silicone type resin.

In the embodiment, the switch element structure 10a is cut from the MEMS element mounting wafer 80, and is sealed in the semiconductor device 90. Accordingly, the semiconductor device 90 has a configuration similar to those of the semiconductor wafer 20a and the sealing wafer 60a shown in the sectional view taken along the line 9(b)-9(b) in FIG. 9(a), except that the groove portion 30a and the protruding portion 50a have the configurations different from those thereof after the MEMS element mounting wafer 80 is cut in pieces.

In the embodiment, the semiconductor device 90 includes the step portion 30b corresponding to the groove portion 30a of the MEMS element mounting wafer 80 and a protruding portion 50b corresponding to the protruding portion 50a of the MEMS element mounting wafer 80. Other components of the semiconductor device 90 similar to those of the MEMS element mounting wafer 80 are designated with the same reference numerals, and explanations thereof are omitted.

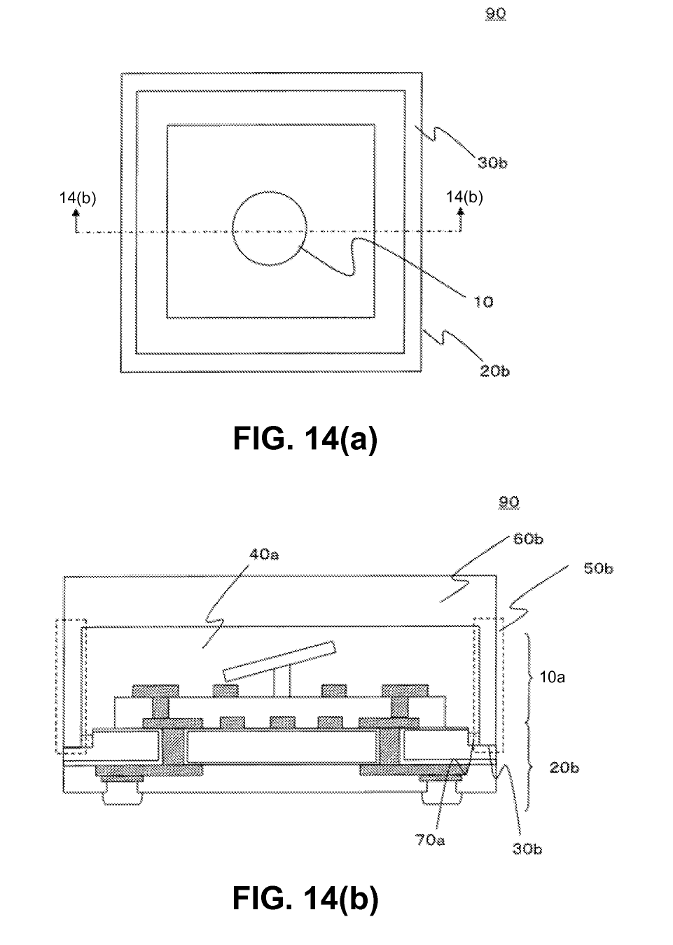

The step portion 30b will be explained in more detail next. FIG. 14(a) is a schematic plan view No. 7 showing the method of producing the semiconductor device 90 according to the first embodiment of the present invention. FIG. 14(b) is a schematic sectional view No. 12 showing the method of producing the semiconductor device 90 taken along a line 14(b)-14(b) in FIG. 14(a) according to the first embodiment of the present invention.

As shown in FIG. 14(a), in a plan view, the step portion 30b is arranged to surround the forming area of the switch element structure 10a along an outer circumference of the semiconductor chip 20b. Further, the step portion 30b has a width of, for example, 125 μm in a direction of the line 14(b)-14(b).

As shown in FIG. 14(b), the step portion 30b has a bottom surface at a level lower than an upper surface of the semiconductor chip 20b by a length of, for example, 150 μm. In FIG. 14(a), the switch element structure 10a is represented with a single circle, and the sealing cap 60b is omitted.

In the embodiment, it is preferred that the bottom surface of the step portion 30b has the undulation pattern 100 shown in FIGS. 7(a)-7(b) and 8(a)-8(d). When the bottom surface of the step portion 30b has the undulation pattern 100, it is possible to increase a bonding area between the semiconductor chip 20b and the sealing cap 60b. Accordingly, when the semiconductor chip 20b is bonded to the sealing cap 60b with the adhesive 70a, it is possible to strongly bond the semiconductor wafer 20a to the sealing cap 60b, thereby increasing air-tightness and reliability of the semiconductor device 90. Further, it is preferred that the undulation pattern 100 has a top portion having a pointed shape or a curved shape (for a reason described later).

In the embodiment, the MEMS element mounting wafer 80 is cut in pieces to obtain the sealing cap 60b. As shown in FIG. 14(b), the sealing cap 60b has a recess portion 40b surrounded by the protruding portion 50b. Further, the sealing cap 60b is bonded to the bottom surface and the side surfaces of the step portion 30b through the protruding portion 50b with the adhesive 70a.

In the embodiment, the protruding portion 50b corresponds to the protruding portion 50a of the MEMS element mounting wafer 80. When the MEMS element mounting wafer 80 is cut in pieces, the protruding portion 50a is cut along the area of the groove portion 30a, thereby forming the protruding portion 50b. Accordingly, the protruding portion 50b has a width in the direction of the line 14(b)-14(b) smaller than that of the protruding portion 50a in the direction of the line 9(b)-9(b) in FIG. 9(a).

In the embodiment, it is preferred that the adhesive 70a has a Young's modulus smaller than that of at least one of the semiconductor chip 20b and the sealing cap 60b. Further, It is preferred that the adhesive 70a is formed of a silicone type resin for a reason described below.

After the semiconductor device 90 is formed, the semiconductor device 90 is exposed to an outer temperature in an actual use. Accordingly, the semiconductor chip 20b and the sealing cap 60b expend or contract according to thermal expansion coefficients thereof.

In the embodiment, the sealing cap 60b is formed of a glass having a thermal expansion coefficient of 3.2×10⁻⁶/° C., and the semiconductor chip 20b is formed of silicon having a thermal expansion coefficient of 24×10⁻⁶/° C. significantly different from that of the sealing cap 60b. Accordingly, when the semiconductor chip 20b and the sealing cap 60b contract due to a change in the outer temperature, the semiconductor chip 20b contracts to a larger extent than the sealing cap 60b since the thermal expansion coefficient of the semiconductor chip 20b is larger than that of the sealing cap 60b. As a result, the semiconductor chip 20b generates a tensional force with respect to the sealing cap 60b formed of a glass.

If the adhesive 70a has a Young's modulus similar to those of the semiconductor chip 20b and the sealing cap 60b after the adhesive 70a is hardened, or the sealing cap 60b is bonded to the semiconductor chip 20b with the anodic bonding method, the sealing cap 60b is strongly bonded to the semiconductor chip 20b. Accordingly, the tensional force applied from the semiconductor chip 20b to the sealing cap 60b is directly transmitted to the sealing cap 60b. When the sealing cap 60b receives the tensional force from the semiconductor chip 20b, the sealing cap 60b tends to contract to a larger extend than that the sealing cap 60b inherently contracts due to the thermal expansion coefficient thereof.

In the case described above, as shown in FIG. 20(a), the sealing cap 60b may be bent in an opposite direction relative to the semiconductor chip 20b. Further, as shown in FIG. 20(b), when the sealing cap 60b is bent excessively, the sealing cap 60b may be broken, thereby lowering yield. Note that arrows in FIG. 20(a) indicate a direction that the sealing cap 60b receives the tensional force from the semiconductor chip 20b.

For the reason described above, in the embodiment, the adhesive 70a has a Young's modulus sufficiently smaller than those of the semiconductor chip 20b and the sealing cap 60b. Accordingly, the adhesive 70a tends to deform more freely due to the smaller Young's modulus, thereby making it possible to alleviate the tensional force applied from the semiconductor chip 20b to the sealing cap 60b.

In general, a glass has a Young's modulus of 65 to 95 MPa, and silicon has a Young's modulus of 160 to 190 MPa. On the other hand, a silicone type resin has a Young's modulus of 0.5 to 20 MPa sufficiently smaller than that of a glass or silicon. Accordingly, the adhesive 70a tends to deform more freely due to the smaller Young's modulus, thereby making it possible to alleviate the tensional force applied from the semiconductor wafer 20a to the sealing wafer 60a.

As described above, in the embodiment, it is preferred that the adhesive 70a has a Young's modulus smaller than those of the semiconductor chip 20b and the sealing cap 60b. Further, it is preferred that the adhesive 70a is formed of a silicone type resin for the reason described above.

As described above, in the embodiment, it is preferred the undulation pattern 100 has the top portion having a pointed shape or a curved shape for a reason described below. When the bottom surface of the step portion 30b has the undulation pattern 100, it is possible to increase a bonding area between the adhesive 70a and the bottom surface of the step portion 30b, thereby improving bonding reliability between the step portion 30b and the protruding portion 50b.

Further, when the undulation pattern 100 has the top portion having a pointed shape or a curved shape, a bonding area between the step portion 30b and the protruding portion 50b decreases. Accordingly, when the semiconductor chip 20b applies the tensional force to the sealing cap 60b due to the difference in the thermal expansion coefficients of the semiconductor chip 20b and the sealing cap 60b upon changing in a temperature, it is possible to alleviate the tensional force. More specifically, when the semiconductor chip 20b and the sealing cap 60b expand or contact due to a temperature change, the adhesive 70a can expand or contact to a large extent due to the small bonding area between the semiconductor chip 20b and the sealing cap 60b. Accordingly, the adhesive 70a disposed between the semiconductor chip 20b and the sealing cap 60b can effectively alleviate a force applied from the semiconductor chip 20b and the sealing cap 60b.

In the embodiment, it is preferred that the buffer layer 35 is disposed between the protruding portion 50b and the bottom surface of the step portion 30b. With the buffer layer 35, when an impact is applied to the semiconductor device 90, it is possible to absorb the impact with the buffer layer 35 disposed between the semiconductor chip 20b and the sealing cap 60b, thereby preventing the semiconductor device 90 from being damaged.

In the embodiment, it is preferred that the buffer layer 35 has a Young's modulus smaller than at least one of the semiconductor chip 20b and the sealing cap 60b. Further, it is preferred that the buffer layer 35 is formed of an epoxy type resin or a polyimide type resin from a manufacturing point of view. More specifically, it is preferred that the buffer layer 35 is formed of a silicone type resin such as a silicone rubber.

In general, a glass has a Young's modulus of 65 to 95 MPa, and silicon has a Young's modulus of 160 to 190 MPa. On the other hand, an epoxy type resin has a Young's modulus of 2.6 to 3.0 MPa; a polyimide type resin has a Young's modulus of 3.0 to 5.0 MPa; and a silicone type resin has a Young's modulus of 0.5 to 20 MPa. Accordingly, the adhesive 70a tends to deform more freely due to the smaller Young's modulus, thereby making it possible to alleviate the tensional force applied from the semiconductor chip 20b to the sealing cap 60b.

In the embodiment, it is preferred that the adhesive 70a does not overflow from the forming area of the step portion 30b, and does not adhere to the switch element structures 10a. When the adhesive 70a adheres to the switch element structures 10a, an adverse effect may affect the property of the switch element 14.

As described above, in the embodiment, the method of producing the semiconductor device 90 includes the steps of: preparing the semiconductor wafer 20a having the recess portions 40a and the protruding portion 50a surrounding the recess portions 40a; filling the adhesive 70a in the groove portion 30a; arranging the semiconductor wafer 20a so that the surface of the semiconductor wafer 20a faces the surface of the sealing wafer 60a; fitting the protruding portion 50a into the groove portion 30a so that the recess portions 40a cover the switch element structures 10a; and hardening the adhesive 70a to form an MEMS element mounting wafer 80. Accordingly, it is possible to alleviate the thermal stress applied from the semiconductor wafer 20a to the sealing wafer 60a due to the difference in the thermal expansion coefficients thereof, thereby improving yield of the semiconductor device 90.

Further, the groove portion 30a is formed in the surface of the semiconductor wafer 20a in the lattice pattern, so that the switch element structures 10a arranged adjacently share the groove portion 30a. Accordingly, as opposed to a case in which a groove is provided for surrounding each of the switch element structures 10a individually, it is possible to form the switch element structures 10a in a large number on one single wafer.

Further, the groove portion 30a may be formed using the dicing blade. Accordingly, it is possible to form the groove portion 30a without using a special mask, thereby reducing a manufacturing cost.

Further, when the undulation pattern 100 is formed on the bottom surface of the groove portion 30a, it is possible to improve bonding of the adhesive 70a relative to the bottom surface of the groove portion 30a, thereby making it possible to form the semiconductor device 90 with high reliability.

Further, the adhesive 70a is filled and hardened such that the adhesive 70a does not overflow into an area other than the groove portion 30a. Accordingly, it is possible to improve operational reliability of the switch element structures 10a.

### Second Embodiment

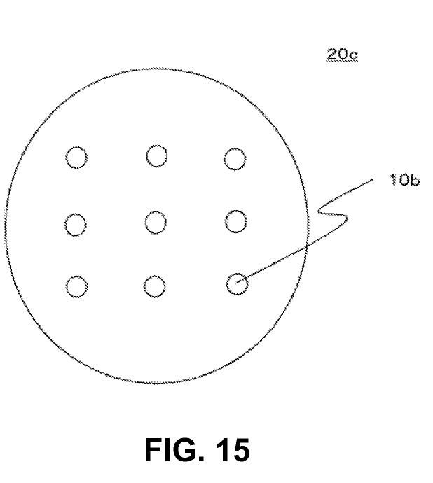

A second embodiment of the present invention will be explained next with reference to FIGS. 15 to 19(a)-19(b).

In the embodiment, a method of producing a semiconductor device 90b includes the steps of: preparing a semiconductor wafer 20c having a plurality of switch element structures 10b as MEMS (Micro Electro Mechanical Systems) elements formed on a surface thereof; forming a groove portion 30c surrounding each of the switch element structures 10b in a surface of the semiconductor wafer 20c; preparing a sealing wafer 60c having a plurality of recess portions 40b formed in a surface thereof and a protruding portion 50c surrounding each of the recess portions 40b; filling an adhesive 70b in the groove portion 30c; arranging the semiconductor wafer 20c, so that the surface of the semiconductor wafer 20c faces the surface of the sealing wafer 60c; fitting the protruding portion 50c into the groove portion 30c, so that the recess portions 40b cover the switch element structures 10b; hardening the adhesive 70b to form an MEMS element mounting wafer 80b; and cutting the MEMS element mounting wafer 80b into pieces. Further, the adhesive 70b is formed of a silicone type resin. The groove portion 30c is formed in the surface of the semiconductor wafer 20c in a ring pattern surrounding each of the switch element structures 10b.

FIG. 15 is a schematic plan view No. 1 showing the method of producing the semiconductor device 90b according to the second embodiment of the present invention.

In the first step, the semiconductor wafer 20c is prepared. As shown in FIG. 15, similar to the first embodiment, a plurality of the switch element structures 10b is formed on the surface of the semiconductor wafer 20c.

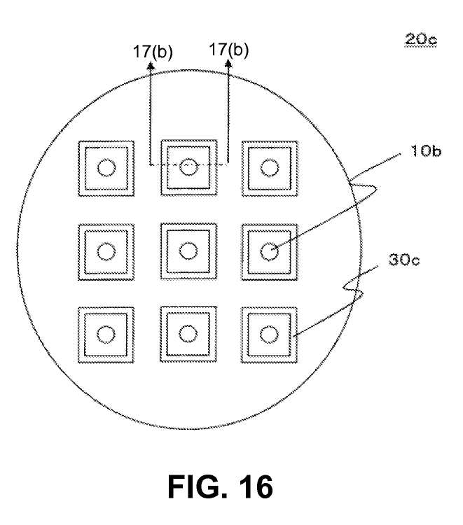

In the next step, the groove portion 30c is formed in the surface of the semiconductor wafer 20c in a ring pattern surrounding each of the switch element structures 10b. FIG. 16 is a schematic plan view No. 2 showing the method of producing the semiconductor device 90b according to the second embodiment of the present invention. As shown in FIG. 16, the groove portion 30c may be formed in the surface of the semiconductor wafer 20c in a ring pattern with a rectangular shape surrounding each of the switch element structures 10b. A shape of the ring pattern may be circular, and is not limited thereto.

In the embodiment, the groove portion 30c has a width of, for example, 150 μm in a direction of a line 17(b)-17(b). Similar to the first embodiment, the groove portion 30c may be formed with a process similar to that shown in FIGS. 13(a)-13(b) to 14(a)-14(b), and not limited thereto. Further, similar to the undulation pattern 100 in the first embodiment, it is preferred that an undulation pattern (not shown) is formed.

In the next step, the sealing wafer 60c is prepared. A plurality of the recess portions 40b is formed in the surface of the sealing wafer 60c, and a plurality of the protruding portions 50c surrounding the recess portions 40b is disposed in the surface of the sealing wafer 60c. The sealing wafer 60c may be formed of a glass.

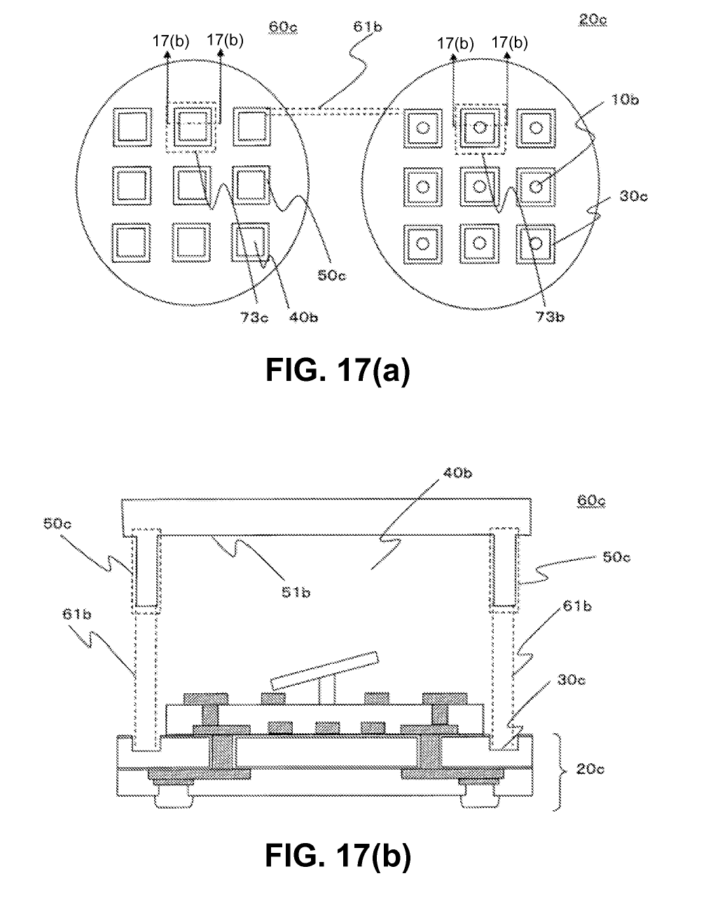

FIG. 17(a) is a schematic plan view No. 3 showing the method of producing the semiconductor device 90b according to the second embodiment of the present invention. FIG. 17(b) is a schematic sectional view No. 1 showing the method of producing the semiconductor device 90b taken along a line 17(b)-17(b) in FIG. 16 and FIG. 17(a) according to the second embodiment of the present invention.

As shown in FIGS. 17(a) and 17(b), a plurality of the recess portions 40b is formed in the surface of the sealing wafer 60a, and a plurality of the protruding portions 50c surrounding the recess portions 40b is disposed on the surface of the sealing wafer 60a.

In the embodiment, the protruding portions 50c protrude from the surface of the sealing wafer 60c, and have a ring pattern. Further, the protruding portions 50c are arranged in areas corresponding to the groove portions 30c as indicated with lines 61b in FIG. 17(a) when the surface of the semiconductor wafer 20c faces the surface of the sealing wafer 60c. The protruding portions 50c have a width of, for example, 100 μm in the direction of the line 17(b)-17(b). Note that each of the recess portions 40b has a bottom surface as a ceiling portion 51b. Each of the switch element structures 10b formed in the semiconductor wafer 20c has the groove portion 30c arranged in an area 73b. The sealing wafer 60c has an area 73c corresponding to the area 73b when the semiconductor wafer 20c faces the sealing wafer 60c.

In the embodiment, similar to the first embodiment, a buffer layer (not shown) may be formed on the bottom surface of the groove portion 30c. The buffer layer may be formed of a material similar to that of the buffer layer 35, thereby obtaining a similar effect.

In the next step, similar to the first embodiment, the adhesive 70b is filled in the groove portion 30c. It is preferred that the adhesive 70b has a Young's modulus smaller than those of the semiconductor wafer 20c and the sealing wafer 60c, and is formed of a silicone type resin such as a silicone rubber. It is preferred that the adhesive 70b is filled in the groove portion 30c such that the adhesive 70b does not overflow in an area other than the groove portion 30c after the adhesive 70b is hardened. When the adhesive 70b overflows out of the groove portion 30c and is attached to the switch element structure 10b, the switch element 14 may malfunction.

In the next step, the surface of the semiconductor wafer 20c faces the surface of the sealing wafer 60c, and the protruding portions 50c are fitted into the groove portions 30c, so that the recess portions 40b covers the switch element structures 10b. In this step, when the protruding portions 50c are fitted into the groove portions 30c, it is preferred that the sealing wafer 60c is pressed against the semiconductor wafer 20c, thereby making it possible to minimize an amount of the adhesive 70b situated at an interface between the protruding portions 50c and the bottom surface of the groove portions 30c. When the sealing wafer 60c is pressed against the semiconductor wafer 20c, it is not necessary to accurately control a film thickness of the adhesive 70b. Accordingly, it is possible to adjust a distance between the ceiling portion 51b and the switch element structures 10b simply through adjusting a length of the protruding portions 50c in a vertical direction relative to the semiconductor wafer 20c in advance.

In the next step, similar to the first embodiment, the adhesive 70b is hardened, so that the semiconductor wafer 20c is bonded to the sealing wafer 60c, thereby forming an MEMS element mounting wafer 80b. When the adhesive 70b is formed of a silicone type resin, it is possible to harden the adhesive 70b at a temperature of 150° C. for a processing time of one hour.

In this step, it is preferred that the adhesive 70b is hardened in a state that the sealing wafer 60c is pressed against the semiconductor wafer 20c. When the sealing wafer 60c is pressed against the semiconductor wafer 20c, it is not necessary to accurately control a film thickness of the adhesive 70b. Accordingly, it is possible to adjust a distance between the ceiling portion 51b and the switch element structures 10b simply through adjusting a length of the protruding portions 50c in a vertical direction relative to the semiconductor wafer 20c in advance.

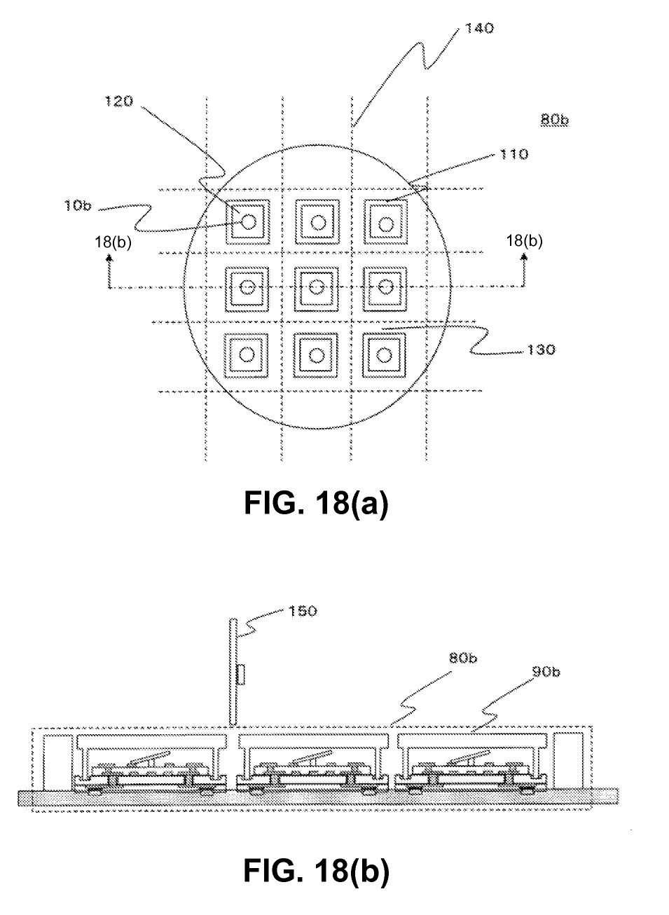

In the next step, the MEMS element mounting wafer 80b is cut in pieces, thereby forming the semiconductor devices 90b. FIG. 18(a) is a schematic plan view No. 4 showing the method of producing the semiconductor device 90b according to the second embodiment of the present invention. FIG. 18(b) is a schematic sectional view No. 2 showing the method of producing the semiconductor device 90b taken along a line 18(b)-18(b) in FIG. 18(a) according to the second embodiment of the present invention.

As shown in FIG. 18(a), the semiconductor wafer 20c includes first areas 110 in which the groove portions 30c are formed; second areas 120 surrounded with the groove portions 30c in which the switch element structures 10b are formed; and third areas 130 situated between the first areas 110. When the MEMS element mounting wafer 80b is cut in pieces, the MEMS element mounting wafer 80b is cut in a vertical direction relative to the surface of the semiconductor wafer 20c along the third areas 130. More specifically, the MEMS element mounting wafer 80b is cut along hidden lines 140 shown in FIG. 18(a).

As shown in FIG. 18(b), a dicing blade 150 cuts the MEMS element mounting wafer 80b such that the dicing blade does not reach the sidewalls of the protruding portions 50c. Alternatively, a laser dicing method may be adopted to cut the MEMS element mounting wafer 80b in pieces. The dicing blade 150 cuts the MEMS element mounting wafer 80b along the third areas 130 where the sealing wafer 60c is not bonded to the semiconductor wafer 20c. Accordingly, the sealing wafer 60c may be chipped. After the last step, the semiconductor devices 90b are completed as shown in FIG. 18(b).

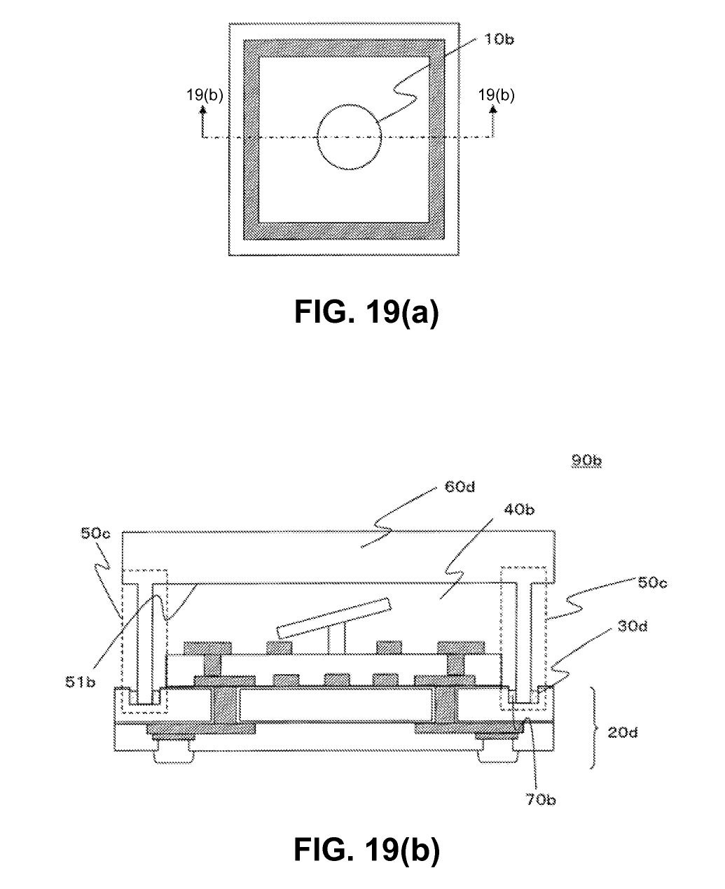

A configuration of the semiconductor device 90b will be explained in more detail next with reference to FIGS. 19(a) and 19(b). FIG. 19(a) is a schematic plan view No. 5 showing the method of producing the semiconductor device 90b according to the second embodiment of the present invention. FIG. 19(b) is a schematic sectional view No. 3 showing the method of producing the semiconductor device 90b taken along a line 19(b)-19(b) in FIG. 19(a) according to the second embodiment of the present invention.

In the embodiment, the semiconductor device 90b includes a semiconductor chip 20d and a sealing cap 60d. The switch element structure 10b as an MEMS element and a step portion 30d surrounding the switch element structure 10b are formed on a surface of the semiconductor chip 20d. The sealing cap 60d is attached to the step portion 30d with the adhesive 70b, so that the sealing cap 60d covers the switch element structure 10b. Further, the step portion 30d includes a bottom surface and side surfaces, so that the bottom surface and the side surfaces of the step portion 30d are bonded to the sealing cap 60d. The adhesive 70b is formed of a silicone type resin. The step portion 30d has a recess shape.

In the embodiment, the MEMS element mounting wafer 80b has a configuration substantially similar to that of the semiconductor device 90b cut from the MEMS element mounting wafer 80b. Accordingly, components of the semiconductor device 90b similar to those of the MEMS element mounting wafer 80b are designated with the same reference numerals, and explanations thereof are omitted.

In the embodiment, the semiconductor device 90b is cut from the MEMS element mounting wafer 80b, and the semiconductor chip 20d corresponds to an area 73b shown in FIG. 17(a), and the sealing cap 60d corresponds to an area 73c shown in FIG. 17(a), respectively.

The step portion 30d will be explained in more detail next. The step portion 30d corresponds to the groove portion 30c. Note that the semiconductor device 90b has a configuration similar to that of the semiconductor device 90 except that the step portion 30d is different from the step portion 30b of the semiconductor device 90.

As shown in FIG. 19(a), the step portion 30d is formed in the surface of the semiconductor chip 20d to surround the switch element structure 10b, and has an arrangement in a plane view different from that of the step portion 30b formed along the outer circumference of the semiconductor chip 20b. More specifically, the step portion 30d is situated inside an outer circumference of the semiconductor chip 20d.

As shown in FIG. 19(b), the step portion 30d is situated inside the outer circumference of the semiconductor chip 20d, and has a recessed sectional shape. When the step portion 30d has the recessed sectional shape, as opposed to the step portion 30b of the semiconductor device 90, the step portion 30d is bonded to the protruding portion 50c over a larger area, i.e., increased by one side surface of the step portion 30d. Accordingly, the step portion 30d is bonded to the sealing cap 60d over a larger bonding area, thereby increasing a bonding strength between the step portion 30d and the sealing cap 60d as opposed to the semiconductor device 90 and improving reliability of the semiconductor device 90b.

In the embodiment, it is preferred that the bottom surface of the step portion 30d has an undulation pattern. Similar to the first embodiment, when the bottom surface of the step portion 30b has the undulation pattern, it is possible to increase a bonding area between the bottom surface of the step portion 30d and the protruding portion 50c, thereby increasing a bonding strength between the semiconductor chip 20d and the sealing cap 60d. Further, it is preferred that the undulation pattern has a top portion having a pointed shape or a curved shape for a reason similar to that in the first embodiment.

In the embodiment, similar to the semiconductor device 90, it is preferred that a buffer layer is disposed between the protruding portion 50c and the bottom surface of the step portion 30d. When an impact is applied to the semiconductor device 90b, it is possible to absorb the impact with the buffer layer disposed between the semiconductor chip 20d and the sealing cap 60d, thereby preventing the semiconductor device 90b from being damaged.

In the embodiment, it is preferred that the buffer layer has a Young's modulus smaller than at least one of the semiconductor chip 20d and the sealing cap 60d. Further, it is preferred that the buffer layer is formed of an epoxy type resin or a polyimide type resin from a manufacturing point of view. More specifically, it is preferred that the buffer layer is formed of a silicone type resin such as a silicone rubber for a reason similar to that in the first embodiment.

In the embodiment, it is preferred that the adhesive 70b has a Young's modulus sufficiently smaller than those of the semiconductor chip 20d and the sealing cap 60d. Further, it is preferred that the adhesive 70b is formed of a silicone type resin such as a silicone rubber for a reason similar to that of the adhesive 70a in the first embodiment.

As described above, in the second embodiment, the step portion 30d is provided as opposed to the first embodiment. Accordingly, it is possible to increase the bonding strength between the semiconductor chip 20d and the sealing cap 60d relative to the semiconductor device 90b, thereby obtaining the semiconductor device 90b with high reliability.

Further, when the bottom surface of the step portion 30d has the undulation pattern, it is possible to increase the bonding area between the bonding strength between the semiconductor chip 20d and the sealing cap 60d, thereby obtaining the semiconductor device 90b with high reliability.

Further, when the buffer layer is disposed between the protruding portion 50c and the bottom surface of the step portion 30d, it is possible to prevent the semiconductor device 90b from being damaged.

Further, the adhesive 70b is filled and hardened such that the adhesive 70b does not overflow into an area other than the groove portion 30c. Accordingly, it is possible to improve operational reliability of the switch element structures 10b.

The disclosure of Japanese Patent Application No. 2008-218941, filed on Aug. 28, 2008, is incorporated in the application by reference.

While the invention has been explained with reference to the specific embodiments of the invention, the explanation is illustrative and the invention is limited only by the appended claims.

What is claimed is:

1. A method of producing a semiconductor device, comprising the steps of:
preparing a semiconductor wafer having an MEMS (Micro Electro Mechanical Systems) element formed on a surface thereof;
forming a groove portion surrounding the MEMS element in the surface of the semiconductor wafer;
preparing a sealing wafer having a recess portion formed in a surface thereof and a protruding portion surrounding the recess portion;
filling an adhesive in the groove portion, said adhesive being formed of a silicone type resin;
arranging the semiconductor wafer so that the surface of the semiconductor wafer faces the surface of the sealing wafer;
fitting the protruding portion into the groove portion so that the recess portion covers the MEMS element;
hardening the adhesive to form an MEMS element mounting wafer; and
cutting the MEMS element mounting wafer into pieces to obtain the semiconductor device.

2. The method of producing the semiconductor device according to claim 1, wherein, in the step of forming the groove portion, said groove portion is formed in a lattice pattern.

3. The method of producing the semiconductor device according to claim 1, wherein, in the step of cutting the MEMS element mounting wafer, said MEMS element mounting wafer is cut with a dicing blade.

4. The method of producing the semiconductor device according to claim 1, wherein, in the step of forming the groove portion, said groove portion is formed in a ring pattern.

5. The method of producing the semiconductor device according to claim 1, wherein, in the step of preparing the semiconductor wafer, said semiconductor wafer includes a first area in which the groove portion is formed; a second areas surrounded with the groove portion in which the MEMS element is formed; and a third area situated between the first area and an adjacent first area.

6. The method of producing the semiconductor device according to claim 5, wherein, in the step of cutting the MEMS element mounting wafer, said MEMS element mounting wafer is cut along the third area in a vertical direction relative to the surface of the semiconductor wafer.

7. The method of producing the semiconductor device according to claim 1, wherein, in the step of filling the adhesive in the groove portion, said adhesive is filled in the groove portion so that the adhesive does not overflow out of the groove portion.

8. A method of producing an MEMS (Micro Electro Mechanical Systems) element mounting wafer, comprising the steps of:
preparing a semiconductor wafer having an MEMS (Micro Electro Mechanical Systems) element formed on a surface thereof;
forming a groove portion surrounding the MEMS element in the surface of the semiconductor wafer;
preparing a sealing wafer having a recess portion formed in a surface thereof and a protruding portion surrounding the recess portion;
filling an adhesive in the groove portion, said adhesive being formed of a silicone type resin;
arranging the semiconductor wafer so that the surface of the semiconductor wafer faces the surface of the sealing wafer;
fitting the protruding portion into the groove portion so that the recess portion covers the MEMS element; and
hardening the adhesive to form the MEMS element mounting wafer.
